(19) United States
(12) Patent Application Publication
(10) Pub. No.: US 2019/0235229 A1
(43) Pub. Date: Aug. 1, 2019

(54) MEMS CONTROL CIRCUIT AND PROJECTOR

(71) Applicant: FUJITSU LIMITED, Kawasaki-shi (JP)

(72) Inventors: Yusuke UJIIE, Kawasaki (JP); Akiko FURUYA, Yokohama (JP); TOMOKI KATOU, Kawasaki (JP); Nobuaki Kawasoe, Yokohama (JP)

(73) Assignee: FUJITSU LIMITED, Kawasaki-shi (JP)

(21) Appl. No.: 16/247,615

(22) Filed: Jan. 15, 2019

(30) Foreign Application Priority Data
Jan. 30, 2018 (JP) 2018-013895

(51) Int. Cl. G02B 26/08; G02B 26/10; G02B 7/198; B81B 7/02; G03B 21/28; G03B 21/20

(52) U.S. Cl. CPC G02B 26/0833; G02B 26/10; G02B 7/198; B81B 2201/042; G03B 21/28; G03B 21/2033; B81B 7/02

(57) ABSTRACT

A micro electro mechanical systems (MEMS) control circuit includes a memory and a processor coupled to the memory and the processor configured to obtain an amplitude mean value of a monitor signal representing an amplitude in a direction of a horizontal axis of an MEMS device every unit time, compare the amplitude mean value with a reference value, and change a driving frequency of the MEMS device in a case where identical comparison results last consecutively a predetermined number of times.

### CROSS-REFERENCE TO RELATED APPLICATION

This application is based upon and claims the benefit of priority of the prior Japanese Patent Application No. 2018-13895, filed on Jan. 30, 2018, the entire contents of which are incorporated herein by reference.

### FIELD

The embodiments discussed herein are related to an MEMS control circuit and a projector including the MEMS control circuit.

### BACKGROUND

Micro electro mechanical systems (MEMS) are used in various fields such as projectors, ink jet heads, scanning microscopes, various sensors, and so forth. A scanning mirror applying the MEMS technology is referred to an MEMS mirror and scan the light beam output from a light source in a predetermined direction. In the application to projectors, the MEMS mirror scans the light beam in horizontal and vertical directions. An image of one frame is projected on the screen by driving the MEMS mirror in the direction of the horizontal axis (high speed axis) to draw the scanning line and to shift the scanning line in the direction of the vertical axis (low speed axis) for each drawing of one horizontal line.

Scanning in the high speed axis direction by the MEMS mirror is performed at the resonance frequency of the MEMS. In a case where the driving frequency of the MEMS mirror coincides with the resonance frequency of the MEMS, the deflection width of the mirror is maximized, and the driving current may be minimized. The MEMS mirror has temperature dependence, and the resonance frequency varies with the temperature change. When the driving frequency deviates from the resonance frequency, the deflection angle of the mirror decreases and the view angle decreases, so that control for causing the driving frequency to follow the resonance frequency is performed.

There is known a technique of adjusting the frequency of a driving signal so that the phase of the driving signal and the phase of the position signal are identical based on a phase difference signal indicating a phase difference between a driving signal for driving the mirror and a position signal on the mirror (See, for example, Japanese Laid-open Patent Publication No. 2015-36782).

### SUMMARY

According to an aspect of the embodiments, a micro electro mechanical systems (MEMS) control circuit includes a memory and a processor coupled to the memory and the processor configured to obtain an amplitude mean value of a monitor signal representing an amplitude in a direction of a horizontal axis of an MEMS device every unit time, compare the amplitude mean value with a reference value, and change a driving frequency of the MEMS device in a case where identical comparison results last consecutively a predetermined number of times.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating a configuration of controlling a known driving frequency;

FIG. 2 is a diagram for explaining a problem with a configuration of controlling the known driving frequency;

FIG. 3 is a schematic diagram illustrating a configuration example of a projector to which the present disclosure is applied;

FIG. 4 is a schematic block diagram illustrating a configuration example of an MEMS control circuit according to a first embodiment;

FIG. 5 is a diagram for explaining a basic operation of the MEMS control circuit according to the first embodiment;

FIG. 6 is a diagram illustrating a specific example of the control of FIG. 5;

FIG. 7 is a diagram illustrating the effect of the control according to the first embodiment (in the case of N=M);

FIG. 8 is a diagram illustrating the effect of the control according to the first embodiment (in the case of N≠M);

FIGS. 9A and 9B are diagrams for explaining the weighting of the number of times used for continuity determination;

FIG. 10 is a diagram illustrating the effect of the control according to the first embodiment in comparison with a comparative example;

FIG. 11 is a flowchart of an operation of the MEMS control circuit according to the first embodiment;

FIG. 12 is a detailed flowchart of a process of updating a reference value (S13) of FIG. 11;

FIG. 13 is a detailed flowchart of a process of comparing a mean value with a reference value (S14) of FIG. 11;

FIG. 14 is a detailed flowchart of updating a driving frequency based on the continuity determination of FIG. 11 (S15);

FIG. 15 is a schematic block diagram illustrating a configuration example of an MEMS control circuit according to a second embodiment;

FIG. 16 is a flowchart of an operation of the MEMS control circuit according to the second embodiment;

FIG. 17 is a detailed flowchart of an initialization process (S22) of FIG. 16;

FIG. 18 is a detailed flowchart of a process of adjusting a weighting coefficient (S224) of FIG. 17;

FIG. 19 is a detailed flowchart of a process of adjusting a step size (S225) of FIG. 17;

FIG. 20 is a schematic block diagram of an MEMS control circuit according to a third embodiment;

FIG. 21 illustrates an example of a correspondence table stored in an initial frequency holding unit;

FIG. 22 is a flowchart of an operation of the MEMS control circuit of the third embodiment;

FIG. 23 is a detailed flowchart of a process of setting an initial value (S31) of FIG. 22; and

FIG. 24 is a detailed flowchart of a process of holding temperature information and driving frequency information (S32) of FIG. 22.

### DESCRIPTION OF EMBODIMENTS

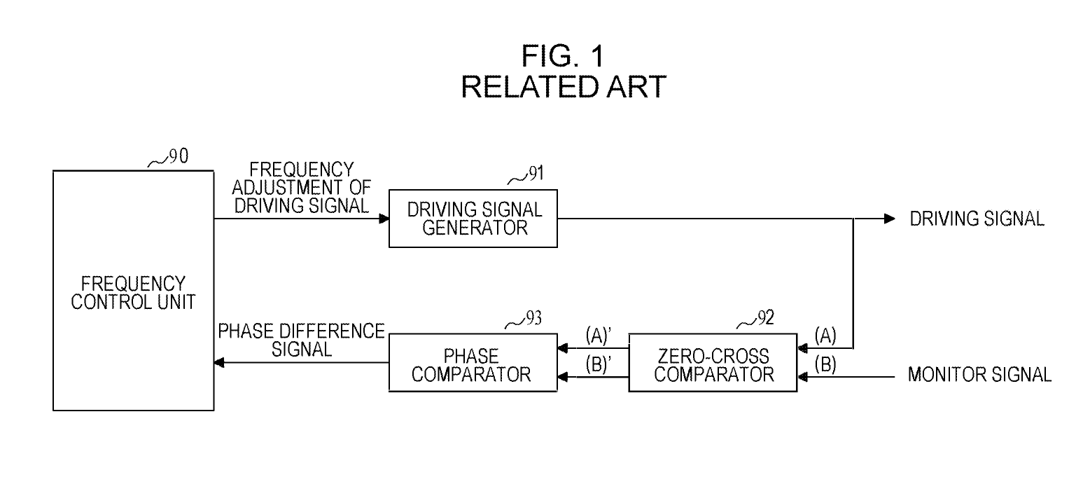

In the method illustrated in FIG. 1, a zero-cross point of a driving signal (A) in the high speed axis direction of an MEMS scanner and a zero-cross point of a monitor signal (B) representing an angle of an MEMS mirror are detected using a zero-cross comparator 92. The zero-cross comparator 92 outputs to a phase comparator 93 a zero-cross point signal (A)′ indicating a zero-cross point of a driving signal and a zero-cross point signal (B)′ indicating a zero-cross point of a monitor signal. The phase comparator 93 compares the phases of the zero-cross point signal (A)′ with the zero-cross point signal (B)′, and outputs a phase difference signal. The frequency control unit 90 adjusts the frequency of the driving signal based on the phase difference signal so that the phase of the driving signal and the phase of the monitor signal are identical.

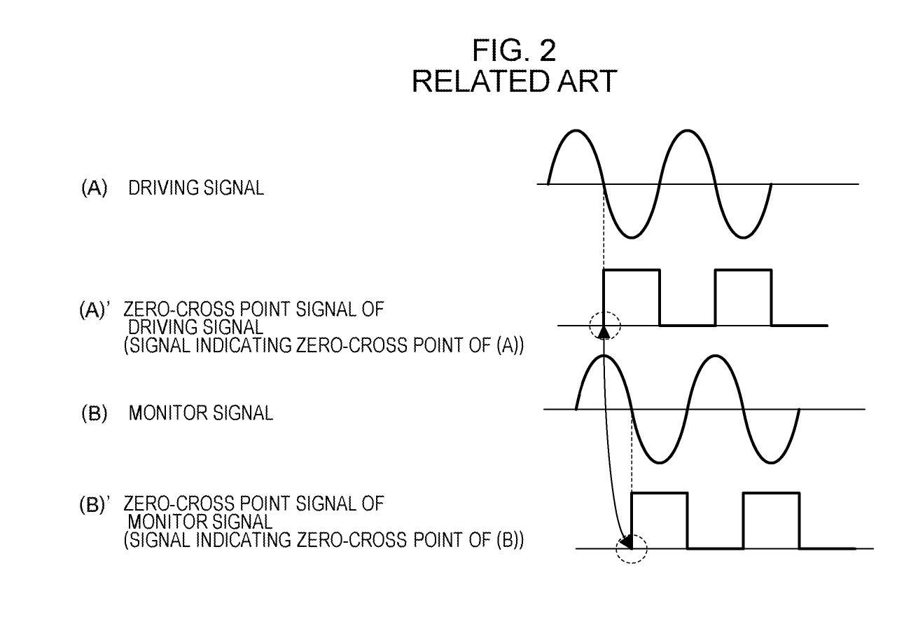

FIG. 2 illustrates the driving signal (A) and its zero-cross point signal (A)′, and the monitor signal (B) and its zero-cross point signal (B)′. The driving signal (A) and the monitor signal (B) are sinusoidal signals. The zero-cross point signals (A)′and (B)′ are rectangular wave signals rising at the zero-cross point.

A monitor signal indicating the position (inclination) of a mirror is obtained based on the change in the capacitance between the mirror and the reference electrode. When the speed of the driving signal increases with the improvement in the resolution, the detection speed of the monitor signal may not follow the speed of the driving signal, thereby reducing the detection accuracy. Even when the method of comparing the phases of the zero-cross points using the zero-cross comparator is employed, a detection error occurs. The similar problem remains even in a case where a digital synchronization detection circuit is used.

An embodiment of an MEMS control technique capable of causing the driving frequency at which the MEMS device is driven to follow a resonance frequency accurately will be described. In the embodiment, the frequency of the driving signal at which the MEMS device is driven (hereinafter referred to as “driving frequency”) is caused to directly follow the resonance frequency from the monitor signal without performing the phase comparison or the phase synchronization, so that the deflection angle (amplitude) of the MEMS device is maintained at the maximum or in the vicinity of the maximum. A state in which the driving frequency and the resonance frequency coincide or is close to each other is held until the time of the next activation.

The resonance frequency is the inherent vibration frequency of the MEMS device to be driven. When the MEMS device is driven at a frequency which coincides with the resonance frequency, the drive range is maximized and the drive current value is minimized.

MEMS devices include various devices such as an MEMS driven mirror, a switch, and a cantilever. In the following embodiments, the MEMS mirror will be described as an example. As an example in which the MEMS mirror is applied, a projector will be described.

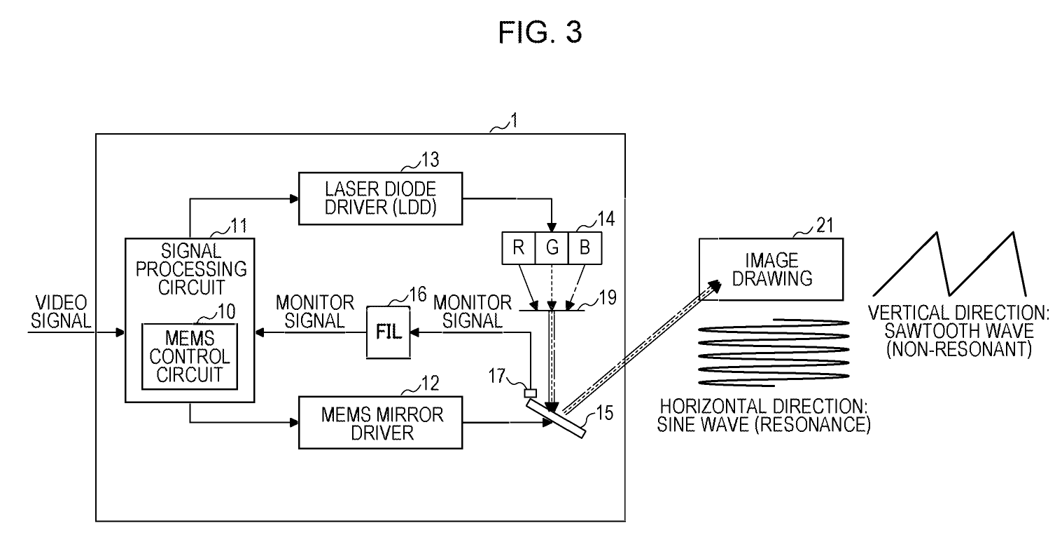

FIG. 3 is a schematic diagram of a projector 1 including an MEMS control circuit 10 according to the embodiment. The projector 1 may be used as a single unit or may be incorporated in a portable terminal such as a smartphone. Alternatively, the MEMS control circuit 10 may be incorporated in a wearable device that is connected to a portable terminal by wire or wirelessly.

The projector 1 includes a signal processing circuit 11, an MEMS mirror driver 12, a laser diode driver (LDD) 13, a light source module 14, an MEMS mirror 15, a filter (FIL) 16, and a monitor 17.

The signal processing circuit 11 includes the MEMS control circuit 10, and is connected to the MEMS mirror driver 12, the LDD 13, and the filter 16. When a video signal is input to the signal processing circuit 11 from the outside, the signal processing circuit 11 outputs, to the LDD 13, an LD driving command for driving the light source module 14 based on the video signal, and outputs, to the MEMS mirror driver 12, a mirror driving command for driving the MEMS mirror 15. The mirror driving command may be output via the MEMS control circuit 10.

The LDD 13 generates and outputs an LD driving signal for driving the light source module 14 based on the LD driving command. The light source module 14 includes light sources of three colors of red (R), green (G), and blue (B), for example, and each of the light sources of three colors is ON/OFF controlled individually by the LD driving signal.

The MEMS mirror driver 12 generates and outputs the mirror driving signal for driving the MEMS mirror 15 based on the mirror driving command. Any method such as an electrostatic type, a piezoelectric type, or an electromagnetic type may be used as a method of driving the MEMS mirror 15. In the embodiment, the electromagnetic type having a relatively large optical deflection angle and performing easy control is used.

The MEMS mirror 15 performs biaxial scanning of a horizontal axis (high speed axis) and a vertical axis (low speed axis) based on the mirror driving command, and draws an image on a screen 21. The screen 21 may not be a white screen or a projection screen, and an image may be projected on a transparent medium such as a windshield glass of an automobile or a spectacle glass.

The operation of the light source module 14 is synchronized with the operation of the MEMS mirror 15. When a red component image is formed on an image forming panel 19, the red image is scanned by the MEMS mirror 15 and projected onto the screen 21. When a green component image is formed on the image forming panel 19, the green image is scanned by the MEMS mirror 15 and projected onto the screen 21. When a blue component image is formed on the image forming panel 19, the blue image is scanned by the MEMS mirror 15 and is projected on the screen 21. Two or more colors of light may be scanned simultaneously. Scanning of each color described above is repeatedly performed in a very short time, and a full color image is formed and displayed on the screen 21.

The MEMS mirror 15 is driven by using a sinusoidal wave of the resonance frequency (resonance mode) in the horizontal axis (high speed axis) direction, and is driven by using a non-resonance mode (or linear mode) in the vertical axis (low speed axis) direction. The high speed operation may be performed in the resonance mode. The non-resonance mode is not suitable for the high speed operation, but may control the deflection angle with high accuracy.

The monitor 17 monitors the angle in the high speed axis direction (mechanical deflection angle) of the MEMS mirror 15 and outputs a monitor signal. The output monitor signal whose unnecessary band components are removed by the filter 16 is input to the MEMS control circuit 10.

According to the related art, it is difficult to control the deflection angle in the resonance mode operating at an high speed with high accuracy even when the phase comparison is performed at the zero-cross point. In the embodiment, the driving frequency of the MEMS mirror 15 is accurately matched to the resonance frequency using the MEMS control circuit 10. The MEMS control circuit 10 directly adjusts the driving frequency from the value of the monitor signal without performing phase comparison or phase synchronization.

### First Embodiment

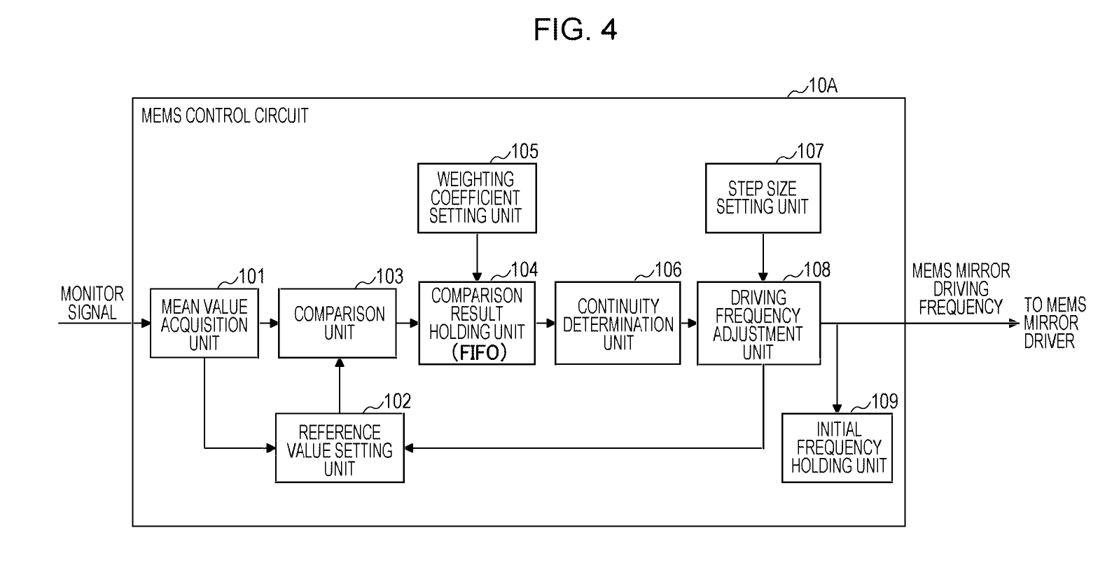

FIG. 4 illustrates the configuration of an MEMS control circuit 10A according to the first embodiment. The MEMS control circuit 10A may be included in part of the signal processing circuit 11 or may be formed as a single integrated circuit chip having a processor and a memory. Part or the whole of the MEMS control circuit 10A may be constructed by a programmable logic device such as a field programmable gate array (FPGA) or a complex programmable logic device (CPLD).

The MEMS control circuit 10A adjusts the frequency of the driving signal so that the deflection angle of the MEMS mirror 15 is maximized by the following method and holds the information of the driving frequency matched to the resonance frequency until the time of the next activation.

(a) The mean value of the deflection angle of the monitor signal is taken every unit time and compared with the reference value. The reference value is the deflection angle mean value obtained immediately after the latest change in the driving frequency.
(b) In a case where the comparison results are consecutively identical a predetermined number of times, the driving frequency of the MEMS mirror is updated with a predetermined step size (adjustment unit). For example, in a case where the deflection angle mean value exceeds the reference value N consecutive times (condition A), the driving frequency is changed by one step in the forward direction. In a case where the deflection angle mean value is less than the reference value M consecutive times (condition B), the driving frequency is changed by one step to the reverse direction.

The values of N and M may be identical or different. Specific values of N and M may be set by input from the outside. During the operation, the values of N and M may be dynamically adjusted or changed. This processing will be described later.

The step size in the case of changing the driving frequency to the forward direction and the step size in the case of changing to the reverse direction may be identical or different. The step size of the driving frequency control in the forward direction may be set smaller than the step size of the driving frequency control to the reverse direction.

Since the reference value is the deflection angle mean value immediately after the driving frequency is changed most recently, it changes with time. Therefore, the reference value used when the control condition A in the forward direction is satisfied and the reference value used when the control condition B to the reverse direction is satisfied may not be identical.

This method makes it possible to cause the driving frequency to follow the resonance frequency even in a case where the resonance frequency of the MEMS mirror 15 fluctuates with environmental changes such as a change in temperature.

(c) The set value of the driving frequency matched to the resonance frequency during the operation of the projector is held until the time of the next activation. On the premise that large environmental changes do not occur until the time of the next activation, the last set value of the driving frequency may be appropriately used as the initial value of the driving frequency of the MEMS mirror 15 at the time of the next activation. Together with the store of the set value, or instead of the store of the set value, the correlation information in which the temperature is associated with the driving frequency (and its adjustment size) may be held.

Referring to FIG. 4, the MEMS control circuit 10A includes a mean value acquisition unit 101, a reference value setting unit 102, a comparison unit 103, a comparison result holding unit 104, a weighting coefficient setting unit 105, a continuity determination unit 106, a step size setting unit 107, a driving frequency adjustment unit 108, and an initial frequency holding unit 109.

The functions of the mean value acquisition unit 101, the reference value setting unit 102, the comparison unit 103, the weighting coefficient setting unit 105, the continuity determination unit 106, the step size setting unit 107, and the driving frequency adjustment unit 108 may be implemented on a arithmetic processing device such as a central processing unit (CPU). Alternatively, the function of the comparison unit 103 may be implemented by a logic circuit such as a comparator, and the function of the continuity determination unit 106 may be implemented by a counter. The function of the comparison result holding unit 104 and the initial frequency holding unit 109 may be implemented by a memory (including a register).

The mean value acquisition unit 101 receives a monitor signal from the monitor 17. Filter processing may be applied to the monitor signal. The monitor signal represents the position or deflection angle of the MEMS mirror 15 to be driven. The deflection angle corresponds to the amplitude of the sinusoidal wave for driving the MEMS mirror 15. The mean value acquisition unit 101 obtains the deflection angle mean value (or amplitude mean value) of the monitor signal every unit time (for example, one frame), and outputs the obtained deflection angle mean value to the reference value setting unit 102 and the comparison unit 103. For example, assuming that the frame rate is 60 Hz, the deflection angle mean value is obtained every 1/60 of a second.

The comparison unit 103 compares the deflection angle mean value for each frame with the reference value set in the reference value setting unit 102 and outputs the comparison result to the comparison result holding unit 104. The reference value is the mean value of deflection angles over a predetermined period immediately after the driving frequency of the MEMS mirror 15 is changed. The predetermined period for determining the reference value may be, for example, an integral multiple of the unit time for calculating the mean value. When one frame is set as the unit time for calculating the mean value, the deflection angle mean value during the period of k frames (k is a positive number) may be obtained.

While the driving frequency is not changed, the latest reference value is maintained. In this case, the deflection angle mean value input per unit time from the mean value acquisition unit 101 to the reference value setting unit 102 may be discarded.

Immediately after the activation of the projector 1, the deflection angle mean value last used at the time of using the previous projector may be set as the reference value. After the activation, until the driving frequency is first adjusted, the deflection angle mean value per frame is compared with the reference value last used at the time of the previous activation.

The comparison result holding unit 104 is, for example, a first in first out (FIFO) register, and comparison results for each unit time (for example, one frame) are sequentially written in the comparison result holding unit 104. The comparison result holding unit 104 may be configured such that in a case where the obtained deflection angle mean value is larger than the reference value, the value “1” may be written, and in a case where the deflection angle mean value is smaller than the reference value, the value “0” may be written.

When the value “1” lasts N consecutive times, the comparison result holding unit 104 outputs the value “1” to the continuity determination unit 106. When the value “0” lasts M consecutive times, the comparison result holding unit 104 outputs the value of “0” to the continuity determination unit 106. The values set in the weighting coefficient setting unit 105 are used as the values of N and M.

The continuity determination unit 106 recognizes, from the output of the comparison result holding unit 104, that identical comparison results have satisfied the driving frequency change condition consecutively for a predetermined number of times. The continuity determination unit 106 determines the change direction of the driving frequency according to the output value from the comparison result holding unit 104, and outputs an adjustment instruction of the driving frequency to the driving frequency adjustment unit 108. When a change in the driving frequency is determined, a value of the comparison results of the predetermined number of times held in the comparison result holding unit 104 may be cleared.

Based on the adjustment instruction, the driving frequency adjustment unit 108 changes the driving frequency to a predetermined direction by one step size. The step size when the driving frequency is adjusted to the forward direction or the reverse direction is set in the step size setting unit 107. The adjustment amount for one step in the forward direction and the adjustment amount for one step to the reverse direction may be identical or different. The adjustment amounts in the forward direction and the reverse direction may be set from the outside.

When the driving frequency is changed, the driving frequency adjustment unit 108 outputs a driving frequency change notification to the reference value setting unit 102. Upon receipt of the driving frequency change notification, the reference value setting unit 102 sets the deflection angle mean value input immediately after the notification as a new reference value and updates the reference value.

While the projector 1 operates, the above-described operation is repeatedly performed, so that the driving frequency follows the resonance frequency.

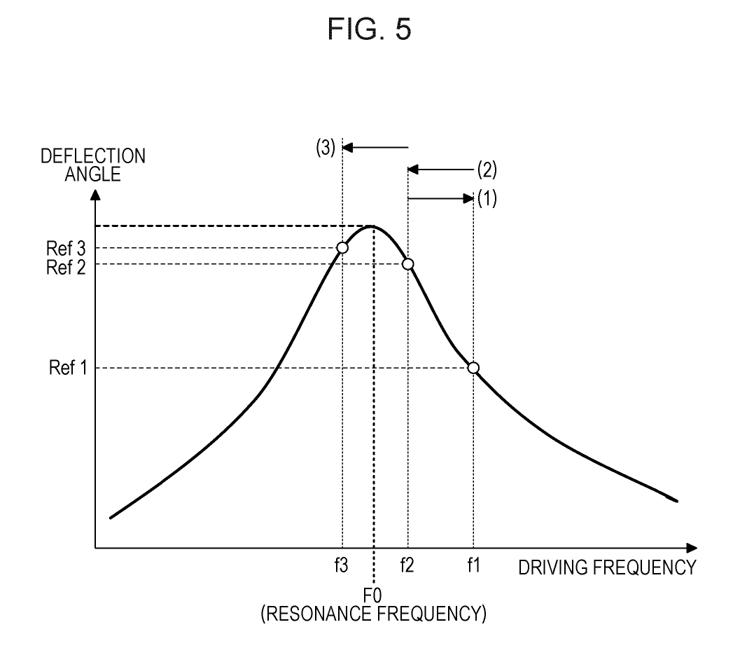

FIG. 5 is a diagram for explaining the basic operation of the MEMS control circuit 10A. Let the resonance frequency of the MEMS mirror 15 be F0. Suppose that either a condition in which the deflection angle mean value per unit time falls below the reference value M consecutive times or a condition in which the deflection angle mean value per unit time exceeds the reference value N consecutive times is satisfied, and the driving frequency is changed from f2 to f1 by one step (arrow (1)). The deflection angle mean value for a predetermined period immediately after the change in the driving frequency is set as a reference value Ref 1 for the next comparison process. The predetermined period for calculating the reference value is, for example, k frames, and may be a period (one frame) identical to the unit time for calculating the mean value for comparison, or may be a multiple of unit time (½ frame, 2 frame, and so forth).

Thereafter, when the deflection angle mean value per unit time falls below the reference value Ref 1 M consecutive times, the driving frequency is changed in a direction (reverse direction) reverse to the previous control direction with a predetermined step size. In FIG. 5, the driving frequency is changed from f1 to f2 (arrow (2)). The reference value is updated due to a change in the driving frequency, and the deflection angle mean value per unit time obtained immediately after this change is set to a new reference value Ref 2.

Thereafter, when the deflection angle mean value consecutively exceeds the reference value Ref 2 N consecutive times, the driving frequency is adjusted in a direction (forward direction) identical to the previous control direction, and is changed from f2 to f3. The deflection angle mean value obtained immediately after this change is set to a new reference value Ref 3. Thereafter, by repeating identical processing, it is possible to converge the driving frequency to the resonance frequency F0.

For convenience sake, the resonance frequency F0 is fixed in FIG. 5. The resonance frequency F0 and the driving frequency f may be in a relative relationship in which the resonance frequency F0 alone may vary, the driving frequency f alone may fluctuate, or both the resonance frequency F0 and the driving frequency f may vary. In this method, the driving frequency is adjusted based on the deflection angle (amplitude) in the high speed axis direction of the MEMS mirror without directly comparing the phases, so that the driving frequency may follow the resonance frequency with high accuracy even in the case of high speed driving.

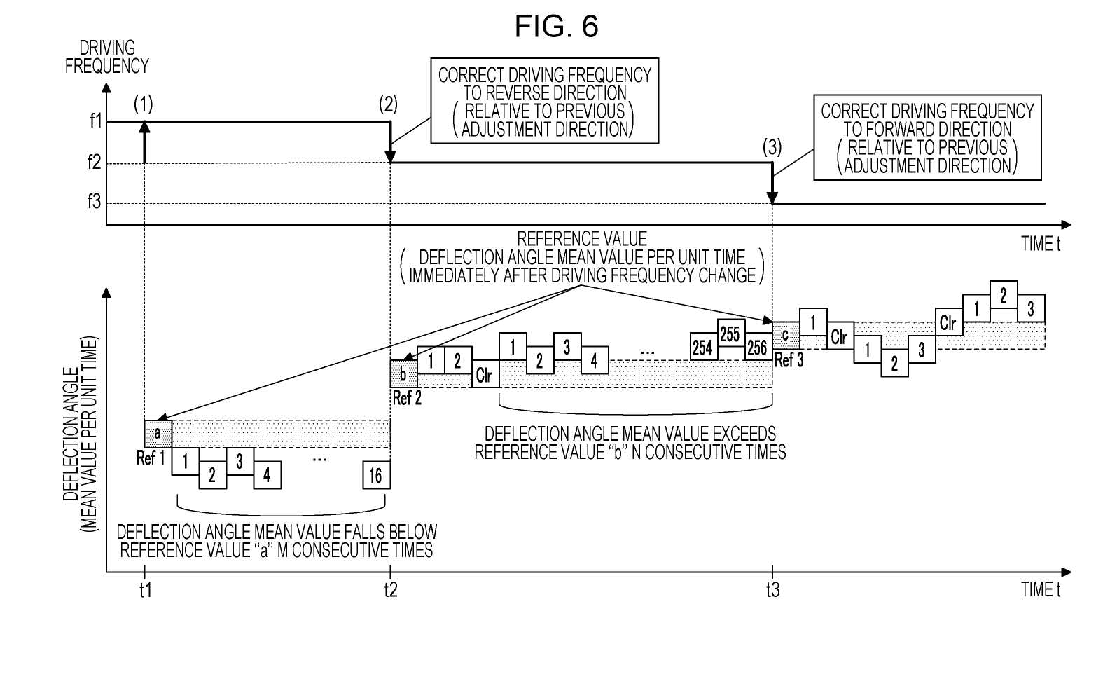

FIG. 6 is a diagram illustrating a specific example of the control of FIG. 5. The horizontal axis represents time (t), and the vertical axis represents the mean value per unit time (1 frame, for example) of the deflection angle of the MEMS mirror 15. At the time t1, in comparison between the mean value per unit time of the monitored deflection angle and the reference value, the condition in which identical comparison results consecutively lasts the predetermined number of times is satisfied. For example, either the condition A in which the deflection angle mean value exceeds the reference value N consecutive times or the condition B in which the deflection angle mean value falls below the reference value M consecutive times is satisfied. Due to satisfaction of this condition, the driving frequency is changed from f2 to f1 (arrow (1)). The deflection angle mean value “a” obtained immediately after the change in the driving frequency is set to the reference value Ref 1, and the subsequent deflection angle mean value is compared with the reference value “a”.

The condition B in which the deflection angle mean value per unit time falls below the reference value “a” M consecutive times (in this example, 16 times) is satisfied at the time t2, and the driving frequency is changed to the direction reverse to the direction of the previous control. The driving frequency is changed from f1 to f2 (arrow (2)). The deflection angle mean value “b” obtained immediately after the time t2 is set to the reference value Ref 2, and the subsequent deflection angle mean value is compared with the reference value “b”.

After the setting of the reference value “b”, the deflection angle mean value exceeds the reference value “b” twice in succession, but decreases to the reference value “b” at the third time, which is different from the previous comparison result, so that the consecutive count is cleared (“Clr”). Consecutive counting starts again from the next frame.

At the time t3, the condition A in which the deflection angle mean value per unit time exceeds the reference value “b” N consecutive times (256 times in this example) is satisfied, and the driving frequency is changed to the direction identical to the direction of the previous control (forward direction). The driving frequency is changed from f2 to f3 (arrow (3)). The deflection angle mean value “c” obtained immediately after the time t3 is set to the reference value Ref 3, and the subsequent deflection angle mean value is compared with the reference value “c”.

When the deflection angle mean value exceeds the reference value “c” once after the setting of the reference value “c”, but decreases to the reference value “c” at the second time, the deflection angle mean value is different from that of the previous comparison result, so that the consecutive count is cleared (“Clr”) and consecutive counting starts from the next frame. When the comparison result changes again after identical comparison results are repeated three times, the continuous count is cleared again, so that counting of the number of times for identical comparison results starts from the next frame.

With this method, it is possible to converge the driving frequency to the resonance frequency from the deflection angle (or amplitude) of the MEMS mirror 15 without performing phase comparison.

In FIG. 6, the fact that the deflection angle mean value falls below the reference value “a” M consecutive times between times t1 and t2 means that the driving frequency is directed to a direction away from the resonance frequency F0 during the M frames. Therefore, the number of consecutive times M of the condition B is set to a value (for example, M=16) smaller than the number of consecutive times of the condition A, and when the driving frequency does not converge for a fixed time, the control is quickly switched to the reverse direction.

The fact that the deflection angle mean value exceeds the reference value “b” N consecutive times between times t2 and t3 means that the driving frequency is approaching the resonance frequency F0 during the N frames, that is, the direction of control is correct. Therefore, in a case where the condition A is satisfied, the control to the forward direction is continued. Modification of the convergence direction to the resonance frequency F0 is not requested. Therefore, the number of consecutive times used in the determination of the condition A may be set to a value (for example, N=256) larger than the number of consecutive times used in the determination of the condition B.

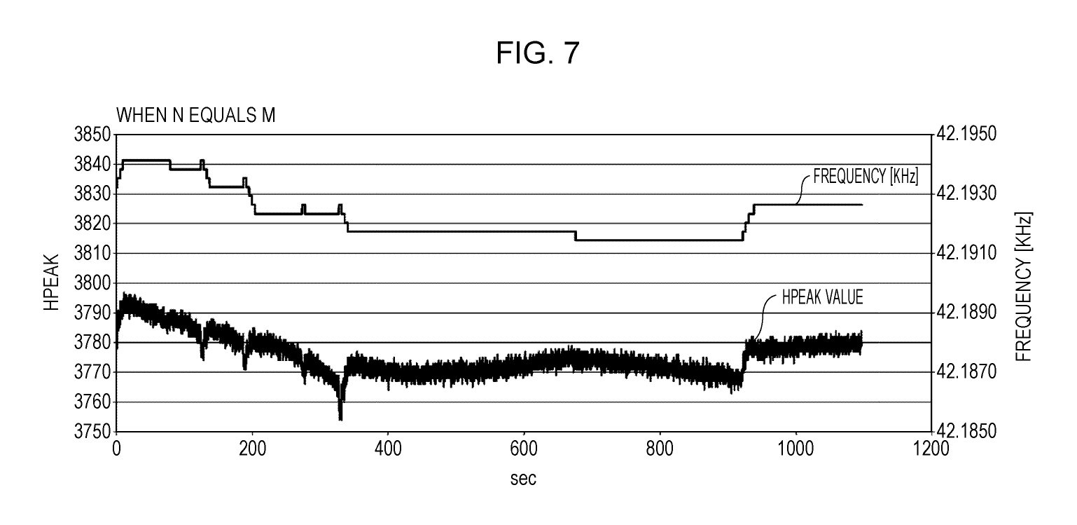

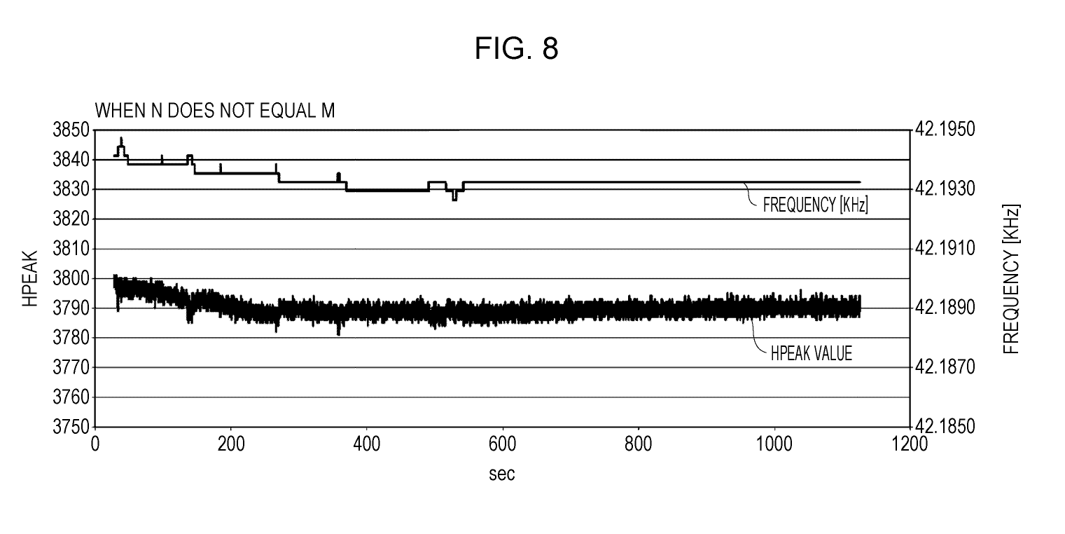

FIGS. 7 and 8 are diagrams illustrating the effects of controlling the driving frequency according to the first embodiment. FIG. 7 illustrates the effect when the N and M of the count value of the continuity determination are identical, and FIG. 8 illustrates the effect when the values of N and M are different. In both figures, the horizontal axis represents time (sec), the vertical axis on the left side represents the maximum value (HPEAK) of the amplitude for each sinusoidal wave of the MEMS monitor signal, and the vertical axis on the right side represents the frequency (kHz).

In FIG. 7, the deflection angle mean value of one frame (60 Hz) is taken and compared with the reference value (deflection angle mean value obtained immediately after the latest driving frequency change). The control conditions are set as follows. • In a case where the deflection angle mean value exceeds the reference value 256 consecutive times, the driving frequency is changed by one step to the forward direction. In a case where the deflection angle mean value falls below the reference value for 256 consecutive times, the driving frequency is changed by one step to the reverse direction. In this condition, N=M=256. The value 256 of N and M is a value selected from the circuit scale in a register transfer level (RTL) design. The step size with which the driving frequency is adjusted is obtained from (Setting value of 8 bit register)×20 MHz/2²⁶, and in FIG. 7, the adjustment amount of one step is 3 kHz.

From FIG. 7, it may be seen that the driving frequency of the MEMS mirror accurately follows the resonance frequency over the period of about 20 minutes from the activation in the configuration according to the first embodiment, and the amplitude variation may be suppressed. However, by setting M and N to the identical value, the driving frequency of the MEMS mirror may fail to respond instantaneously to the shift of the resonance frequency (decrease in deflection angle) due to the temperature fluctuation. In FIG. 7, an instantaneous drop in HPEAK occurred between 200 seconds and 400 seconds, which represents a delay in following the resonance frequency. Therefore, as illustrated in FIG. 8, the weighting of the number of times of continuity determination in the forward direction is different from that in the reverse direction.

In FIG. 8, the control conditions based on the comparison of the deflection angle mean value of one frame (60 Hz) and the reference value are set as follows. • In a case where the deflection angle mean value exceeds the reference value 256 consecutive times, the driving frequency is changed by one step to the forward direction. • In a case where the deflection angle mean value falls below the reference value 16 consecutive times, the driving frequency is changed by one step to the reverse direction.

Under this condition, the value of M is set smaller than the value of N by weighting the number of consecutive times. By setting M to a small value, the direction of control is quickly corrected to cause the resonance frequency to converge in a case where the control of the driving frequency is directed to a direction away from the resonance frequency. In FIG. 8, the amplitude variation may be suppressed for about 20 minutes from the start, and the deflection angle may be stably maintained at the maximum or in the vicinity of the maximum.

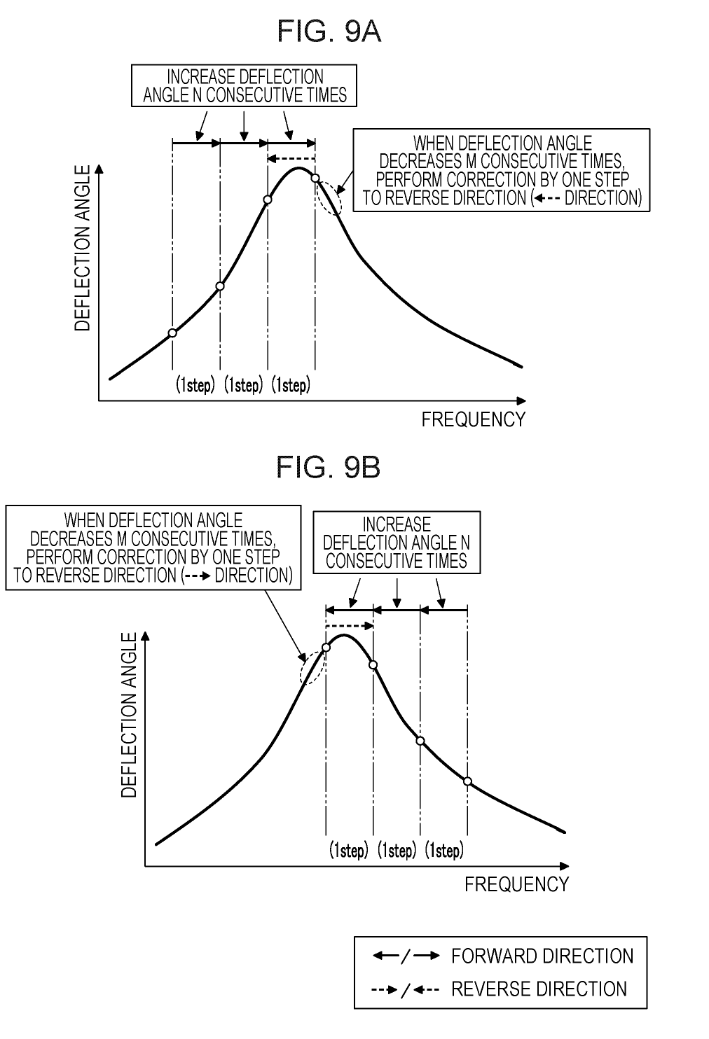

FIGS. 9A and 9B are diagrams for explaining the weighting of the number of times used for continuity determination. As described above, the correction of the driving frequency to the forward direction is a correction for bringing the driving frequency close to the resonance frequency. The correction of the driving frequency to the reverse direction is a correction for directing the driving frequency to a direction reverse to the direction of the previous control in a case where the driving frequency relatively moves away from the resonance frequency.

From this viewpoint, by decreasing the number of consecutive times used for correction to the reverse direction (N>M), the follow-up speed to the resonance frequency is improved.

In FIG. 9A, as indicated by solid arrows, segments where the deflection angle mean value exceeds the reference value N consecutive times (for example, 256 times) last 3 times, and the driving frequency is raised by 3 steps, thereby exceeding the peak of the resonance frequency. In this case, one step is adjusted to the reverse direction (the direction of the arrow of broken line) in a case where the condition in which the deflection angle mean value falls below the reference value M consecutive times (for example, 16 times) is satisfied, so that the direction of control may be corrected.

In FIG. 9B, as indicated by the solid arrow, segments in which the deflection angle mean value exceeds the reference value N consecutive times last 3 times, and the driving frequency is lowered by 3 steps, thereby exceeding the peak of the resonance frequency. In this case, one step is adjusted to the reverse direction (the direction of the arrow of broken line) in a case where the condition in which the deflection angle mean value falls below the reference value M consecutive times is satisfied, so that the direction of control may be corrected.

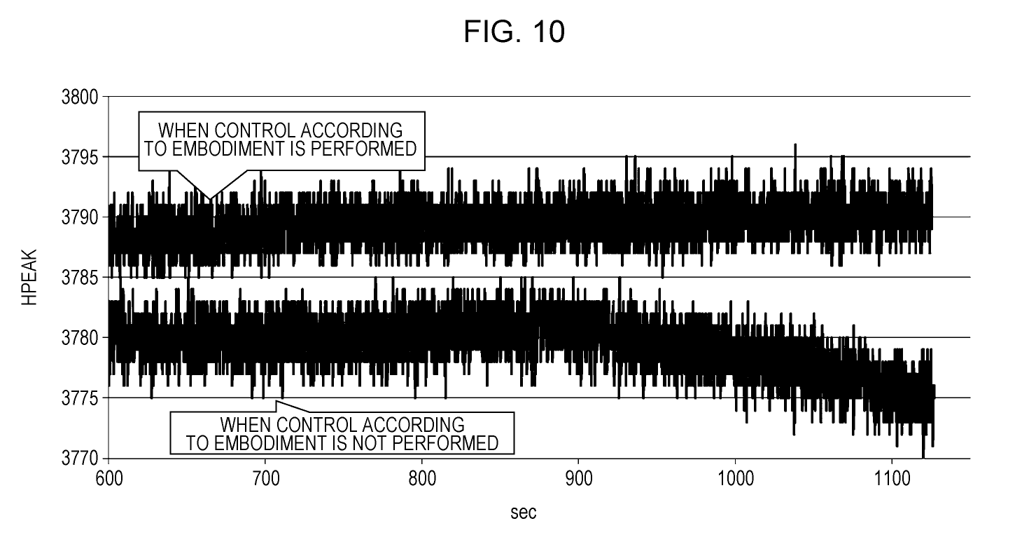

FIG. 10 is a diagram illustrating the effect according to the first embodiment. As a comparative example, simulation results when the driving frequency control according to the first embodiment is not performed are illustrated. The horizontal axis represents time (second), and the vertical axis represents deflection angle peaks (HPEAK) in the high speed axis direction of the MEMS mirror 15. Data from 10 minutes to around 20 minutes after startup are illustrated.

For the MEMS mirror 15 whose resonance frequency fluctuates according to the temperature characteristic, the deflection angle (the sinusoidal wave amplitude HPEAK in the high speed axis direction) may be maximized and may be made invariant by adjusting the driving frequency in the configuration according to the first embodiment, compared with the case of the comparative example. Furthermore, compared to the comparative example, the amplitude fluctuations may be improved by 30%.

It is possible to shorten the time to match the driving frequency to the resonance frequency at the time of the next operation by holding the driving frequency adjusted by the method according to the first embodiment as the initial value of the driving frequency at the time of the next activation. According to the method of the first embodiment, it is possible to omit the synchronous detection circuit and the phase comparison circuit which have been used in the related art.

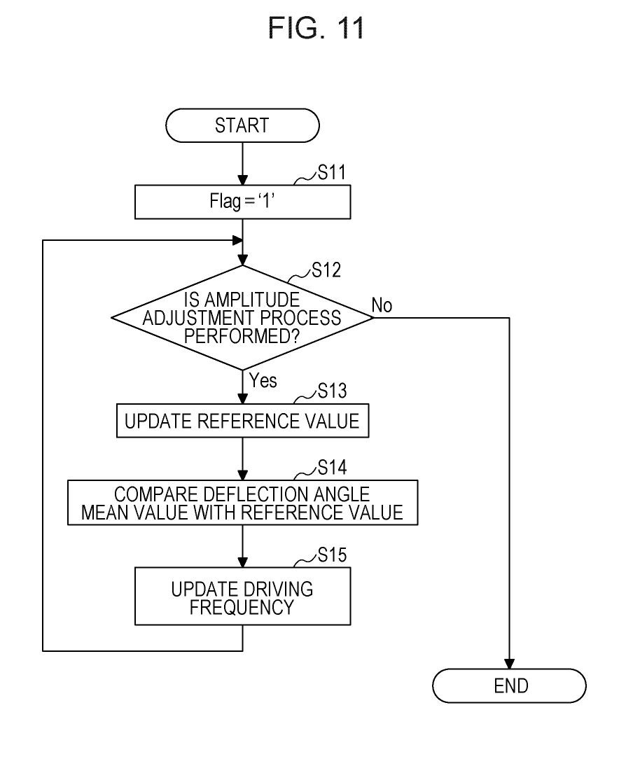

FIG. 11 is a flowchart of the operation of the MEMS control circuit 10. When the projector 1 is activated, the flag is set to “1” (S11), and it is determined whether to adjust the driving frequency, that is, to perform an adjustment process of maintaining the deflection angle (amplitude) of the MEMS mirror at the maximum (S12). In a case where the flag is set to “1”, it is determined that the adjustment process is performed (“Yes” in S12), and the reference value is updated (S13). In the initial process immediately after power-on, the reference value that has been held last at the time of the preceding projector activation may be used as the reference value. The deflection angle mean value of the monitor signal is compared with the reference value (S14), and the driving frequency is updated based on the result of the continuity determination on the comparison values (S15). Processes S12 to S13 are repeatedly performed until the operation of the projector 1 is completed and the amplitude adjustment process is completed (“No” in S12).

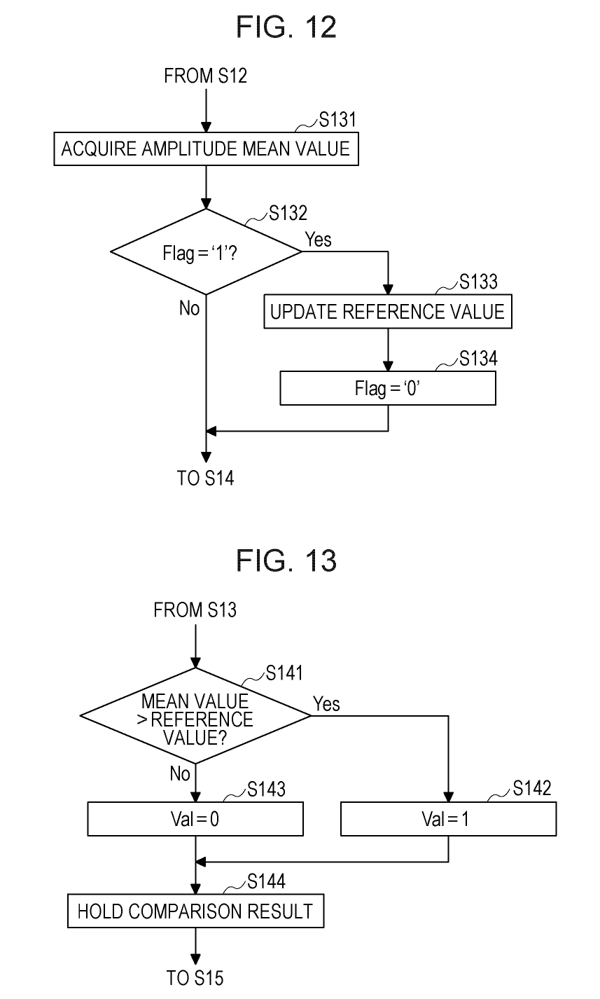

FIG. 12 is a detailed flowchart of a process of updating the reference value in operation S13 of FIG. 11. When the amplitude adjustment process is determined in operation S12, an deflection angle mean value (amplitude mean value) of the MEMS mirror 15 is acquired based on the monitor signal (S131), and the value of the flag is determined (S132). In a case where the flag is “1” (“Yes” in S132), the reference value is updated (S133), and the flag is returned to “0” (S134) and then the process proceeds to operation S14. The fact that the flag is “1” in operation S132 indicates that there is a change in the driving frequency, and the deflection angle mean value initially acquired first after the preceding change in the driving frequency is set as the reference value. In a case where the flag is not “1” (“No” in S132), the previous reference value is maintained without updating the reference value, and the process proceeds to operation S14.

FIG. 13 is a detailed flowchart of a process of comparing a mean value with a reference value in operation S14 of FIG. 11. When the process of updating or maintaining the reference value is performed in operation S13, the deflection angle mean value per unit time is compared with the reference value (S141). In a case where the deflection angle mean value is larger than the reference value (“Yes” in S141), the value of the comparison result is set to “1” (S142), and this value is written in the comparison result holding unit 104 (S144). In a case where the deflection angle mean value is not larger than the reference value (“No” in S141), the value of the comparison result is set to “0” (S143), and this value is written in the comparison result holding unit 104 (S144). Upon completion of the comparison process, the process proceeds to operation S15.

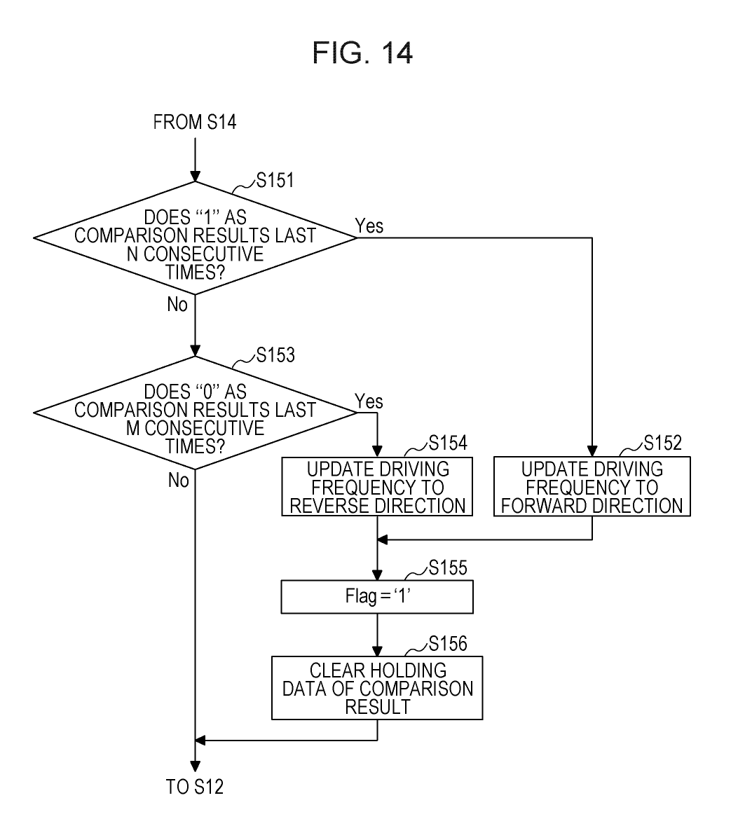

FIG. 14 is a detailed flowchart of updating a driving frequency based on the continuity determination in operation S15 of FIG. 11. When the comparison process is performed in operation S14, the continuity determination unit 106 determines whether the value “1” lasts N consecutive times (S151). In a case where “1” lasts N consecutive times (“Yes” in S151), the driving frequency is changed by one step to the forward direction (S152).

In a case where “1” does not last N consecutive times (“No” in S151), it is determined whether “0” lasts M consecutive times (S153). In a case where “0” lasts M consecutive times (“Yes” in S153), the driving frequency is changed by one step to the reverse direction (S154).

Thereafter, the flag is set to “1” (S155), the data recorded in the comparison result holding unit 104 is cleared (S156), and the process from operation S12 is repeated. As a result, during the operation of the projector, the driving frequency of the MEMS mirror 15 may converge to the resonance frequency, and the deflection angle of the MEMS mirror 15 may be maximized.

### Second Embodiment

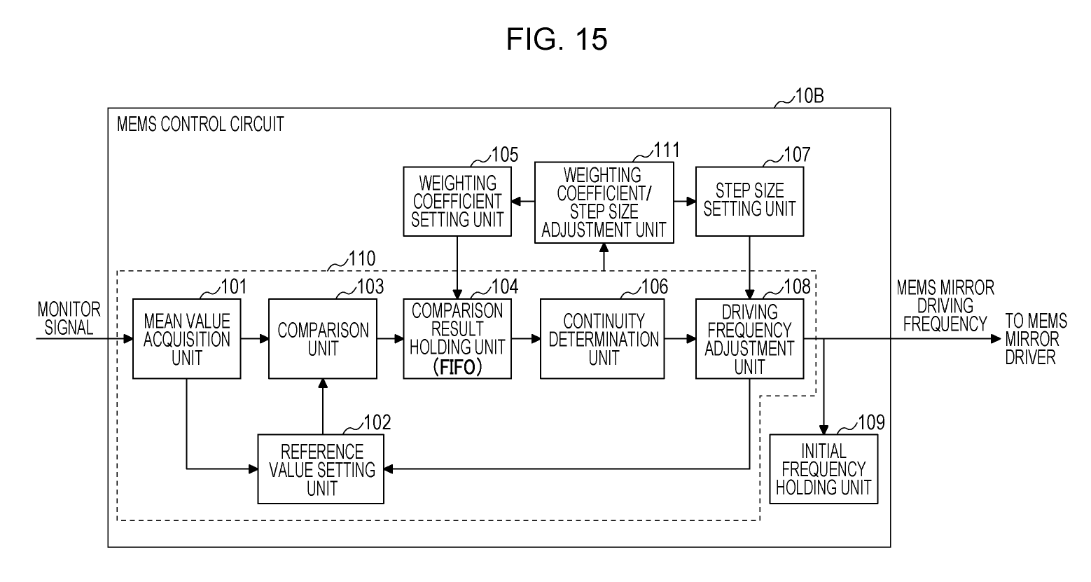

FIG. 15 is a schematic block diagram of an MEMS control circuit 10B according to the second embodiment. The identical reference numerals are given to constituent elements identical to those of the MEMS control circuit 10A according to the first embodiment, and redundant explanations are omitted.

In the second embodiment, during the operation of the projector 1, at least one of the number of consecutive times (N, M) used for determining whether to update the driving frequency and the adjustment step size is dynamically controlled. Since the state of fluctuations of the resonance frequency, the operation state of the MEMS mirror 15, and so forth are different at the time of each process, it is desirable to set the optimum value according to the use state instead of using a fixed value.

The MEMS control circuit 1013 includes a weighting coefficient/step size adjustment unit 111, the weighting coefficient setting unit 105, the step size setting unit 107, a main control unit 110, and the initial frequency holding unit 109. The main control unit 110 includes the mean value acquisition unit 101, the reference value setting unit 102, the comparison unit 103, the comparison result holding unit 104, the weighting coefficient setting unit 105, the continuity determination unit 106, the step size setting unit 107, and the driving frequency adjustment unit 108, and performs the basic operation of controlling the driving frequency described in the first embodiment. As in the first embodiment, the initial frequency holding unit 109 holds the initial value of the driving frequency used at the time of the next activation.

Using the result obtained by the main control unit 110, the weighting coefficient/step size adjustment unit 111 adjusts the weighting coefficient for continuity determination and the step size of the driving frequency update wherein the weighting coefficient is set in the weighting coefficient setting unit 105 and the step size is set in the step size setting unit 107.

The weighting coefficient/step size adjustment unit 111 has a first threshold value used for determining the necessity of changing the weighting coefficient and a second threshold value used for determining the necessity of changing the step size. The first threshold value and the second threshold value may be set through the user's input.

The weighting coefficient of the number of consecutive times is adjusted as follows, for example. When the difference (absolute value) between the deflection angle mean value and the reference value per unit time is smaller than the first threshold value during the control of the driving frequency to the forward direction, the weighting coefficient is determined so as to decrease the number of consecutive times N of the forward direction. The fact that the difference between the deflection angle mean value and the reference value is small means that the driving frequency has relatively small fluctuations and is operating stably. In this case, the number of consecutive times is reduced to smoothly adjust the driving frequency to the forward direction. Conversely, the fact that the difference between the deflection angle mean value and the reference value exceeds the first threshold value means that the driving frequency is large fluctuations. In this case, the number of consecutive times N is increased and a change to the forward direction is carefully determined.

During the control to the reverse direction, when the absolute value of the difference between the deflection angle mean value and the reference value exceeds the first threshold value, the weighting coefficient is determined so as to decrease the number of consecutive times M of the reverse direction, and the control direction is corrected quickly. When the difference between the deflection angle mean value and the reference value is smaller than the first threshold value, the number of consecutive times M is increased to reliably determine the necessity of a change to the reverse direction.

The change in the step size is determined as follows. In a case where the number of times of changing the driving frequency to the forward direction lasts beyond the second threshold value, the step size is increased to shorten the convergence time to the resonance frequency. The fact that the number of corrections to the forward direction lasts means that the driving frequency and the resonance frequency are distant from each other, so that the control time may be shortened by increasing the adjustment amount per one time.

In a case where the number of times of changing the driving frequency to the reverse direction lasts beyond the second threshold value, the step size is reduced to narrow the driving frequency to the vicinity of the resonance frequency. The fact that the correction to the reverse direction lasts means that the driving frequency moves back and forth near the resonance frequency. The adjustment amount per one time is reduced, and the range where the driving frequency moves back and forth near the resonance frequency is narrowed, thereby improving the convergence accuracy to the resonance frequency.

This process makes it possible to dynamically and flexibly perform the operation of causing the driving frequency of the MEMS mirror 15 to follow the resonance frequency during the activation of the projector 1.

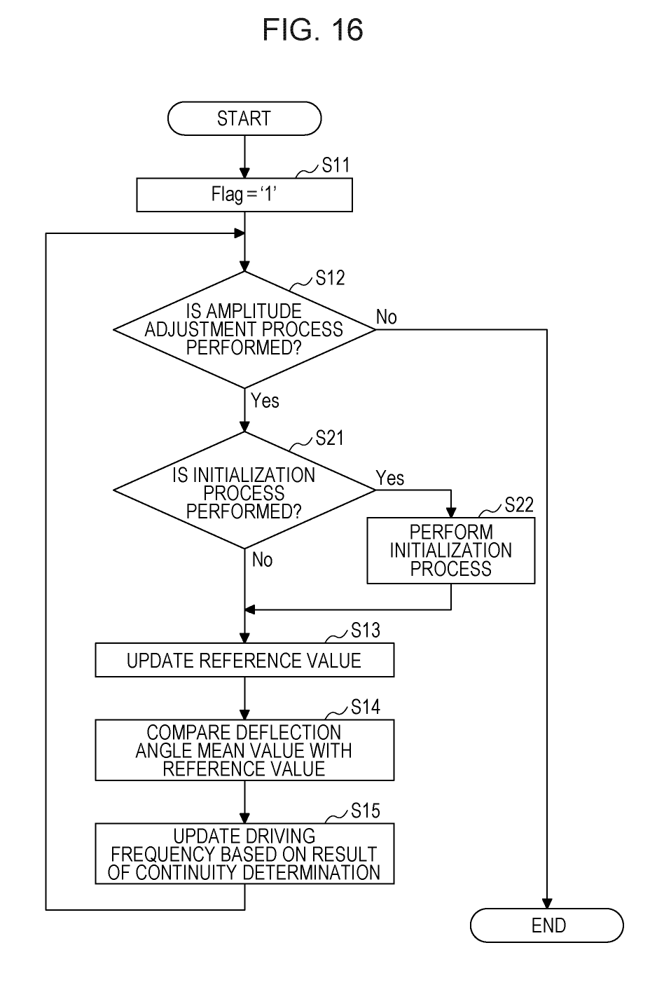

FIG. 16 is a flowchart of an operation of the MEMS control circuit 10B according to the second embodiment. The identical operation numbers are assigned to processes identical to those in FIG. 11 (first embodiment), and redundant explanation is omitted. In FIG. 16, the process of dynamically updating at least one of the weighting of the number of consecutive times (M, N) used for determining whether to update the driving frequency and the adjustment step size is referred to as a initialization process. This “initialization” is not the initialization of the driving frequency, but the initialization or update of the number of consecutive times and adjustment step size.

When the projector 1 is activated and the flag is set to “1” (S11), and the adjustment process of the driving frequency is started (“Yes” in S12), it is determined whether to perform an initialization process with respect to the number of consecutive times (weighting) of the identical comparison results used for determining whether to update the driving frequency and the step size with which the driving frequency is adjusted (S21). In the case of performing the initialization process (“Yes” in S21), the operations S13 to S15 described with reference to FIGS. 11 to 14 are performed after the number of consecutive times (weighting) and the adjustment step size are reset (S22). During the operation of the projector 1, the operations S12, S21 to S22, and S14 to S15 are repeated, and the number of consecutive times (N, M) and the adjustment step size are dynamically adjusted in accordance with the convergence state of the driving frequency to the resonance frequency.

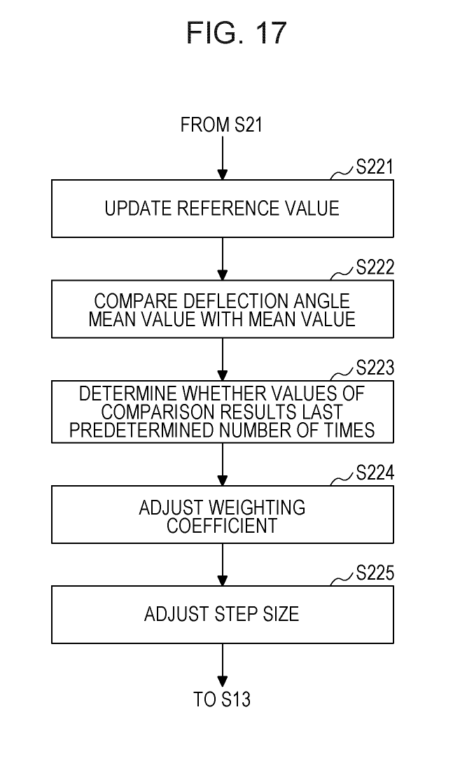

FIG. 17 is a detailed flowchart of the initialization process in operation S22 of FIG. 16. When the initialization process is determined in S21, the reference value is updated (S221). The reference value is updated, for example, by obtaining the deflection angle mean value for a predetermined period (for example, for k frames) immediately after the initialization process is determined.

Next, the deflection angle mean value per unit time is compared with the reference value set in S221 (S222). Next, it is determined whether values of the comparison results last a predetermined number of times (S223). Simultaneously with or before or after this determination process, the adjustment of weighting coefficient of the number of consecutive times and the adjustment of the step size with which the driving frequency is adjusted (S225) are performed (S224). The adjustment of the weighting coefficient (S224) and the adjustment of the step size (S225) may be performed in random order or may be performed in parallel.

When operations of initializing the weighting coefficient and the adjustment step size are completed, operations after operation S13 of FIG. 15 are performed.

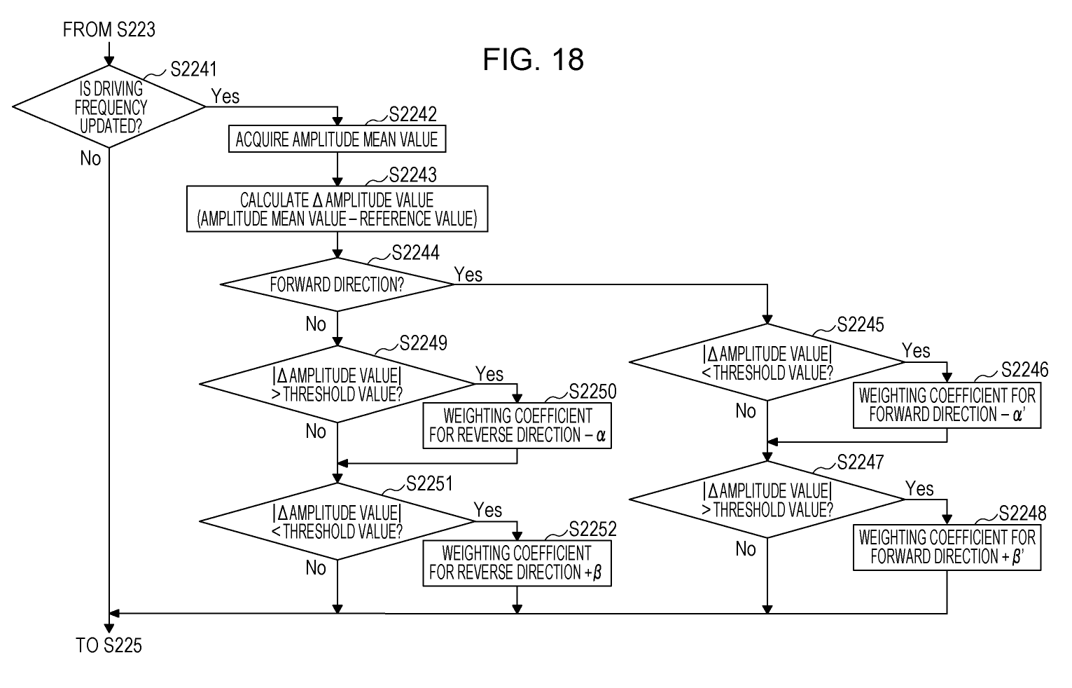

FIG. 18 is a detailed flowchart of a process of adjusting the weighting coefficient adjustment in operation S224 of FIG. 17. This process may be performed by the weighting coefficient/step size adjustment unit 111 based on the output of the main control unit 110.

After operation S223, it is determined whether to update the driving frequency (S2241). The driving frequency is updated in a case where identical comparison results last a predetermined number of times. In the case where the driving frequency is updated (“Yes” in S2241), a deflection angle (amplitude) mean value per unit time is acquired (S2242), and a difference (Δ amplitude value) between the acquired deflection angle mean value and the reference value is calculated (S2243).

It is determined whether the current direction of control is the forward direction (S2244). In a case of the forward direction (“Yes” in S2244), it is determined whether the difference (the absolute value of the Δ amplitude value) is smaller than the first threshold value (S2245). In a case where the A amplitude value is smaller than the first threshold value (“Yes” in S2245), the weighting coefficient for the forward direction is decreased by αa′ (S2246). For example, in a case where N is set to 256, the weighting coefficient is changed to a value smaller than 256 (128 times for example).

In a case where the Δ amplitude value is not smaller than the first threshold value in the forward direction control (“No” in S2245), it is determined whether the Δ amplitude value exceeds the first threshold value (S2247). In a case where the Δ amplitude value exceeds the first threshold value (“Yes” in S2247), the value N for continuity determination on the forward direction is increased by β′(S2248).

In a case where the current control direction is not the forward direction (“No” in S2244), it is determined whether the absolute value of the A amplitude value is larger than the first threshold value (S2249). In a case where the absolute value of the Δ amplitude value is larger than the first threshold value, the number of times (value of M) used for continuity determination on the reverse direction is decreased by α (S2250). As a result, when the fluctuations of the deflection angle of the MEMS mirror 15 increases, the control direction is quickly changed and corrected.

In a case where the absolute value of the Δ amplitude value is smaller than the first threshold value, the number of times (value of M) used for continuity determination on the reverse direction is increased by β (S2252).

When the fluctuations of the deflection angle of the MEMS mirror 15 is small, the operation of changing the control direction is carefully performed.

The adjustment values α, α′, β, and β′ of the number of consecutive times N and M may be set from the outside and may be changed as appropriate. The first threshold value used in the threshold determination (S2245) on the forward direction control and the first threshold value used for the threshold determination on the reverse direction control (S2249) may be different.

This method makes it possible to dynamically adjust the weighting coefficient for continuity determination in accordance with the convergence state of the driving frequency of the MEMS mirror 15 to the resonance frequency, thereby improving the control accuracy.

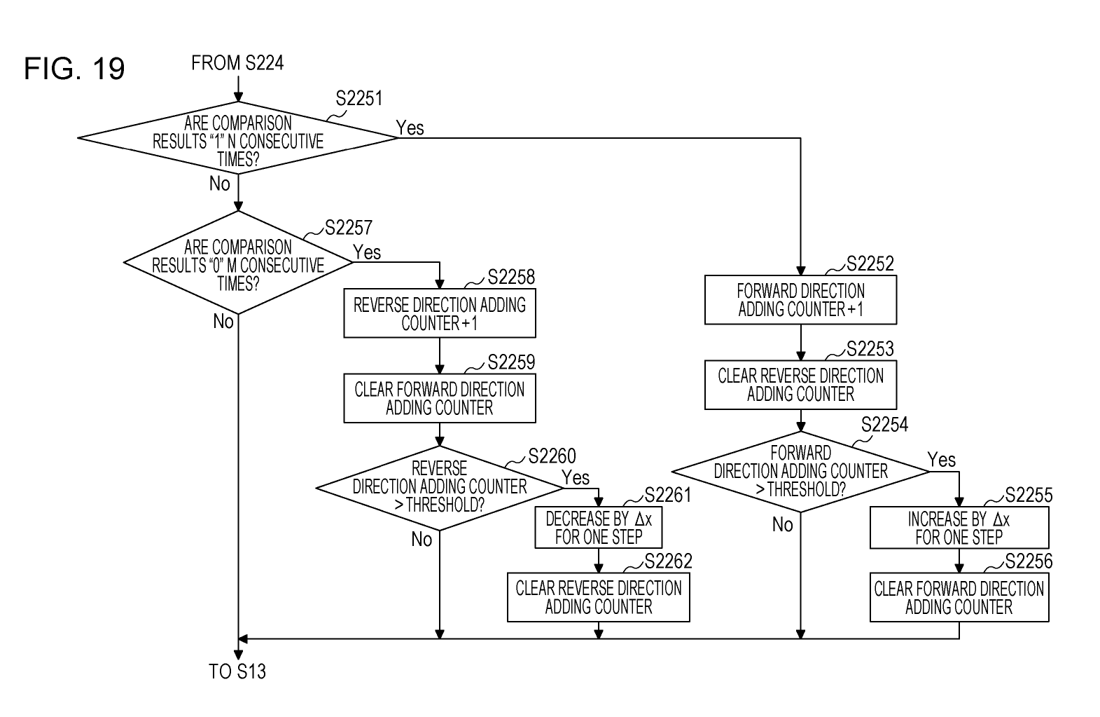

FIG. 19 is a detailed processing flow of a process of adjusting the step size in operation S225 of FIG. 17. This process may be performed by the weighting coefficient/step size adjustment unit 111 based on the output of the main control unit 110.

First, it is determined whether the comparison result between the average deflection angle value per unit time and the reference value indicates the value “1” N consecutive times (S2251). The value “1” indicates that the deflection angle mean value is larger than the reference value. In a case where the comparison result between the average deflection angle value per unit time and the reference value indicates the value “1” N consecutive times, the value of the adding counter that counts the number of times of consecutive changes in the driving frequency to the forward direction is incremented (S2252), and the value of the adding counter that counts the number of times of consecutive changes to the reverse direction is cleared (S2253). As a result of the increment, it is determined whether a value of the adding counter for the forward direction exceeds the second threshold value (S2254). In a case where the value of the adding counter for the forward direction exceeds the second threshold value (“Yes” in S2254), the adjustment amount for one step is increased by Δx (S2255), and the value of the adding counter for the forward direction is cleared (S2256).

In a case where the comparison result does not indicate the value “1” N consecutive times (“No” in S2251), it is determined whether the value “0” of the comparison result lasts M consecutive times (S2257). The value “0” indicates that the deflection angle mean value is smaller than the reference value. In a case where the value “0” of the comparison result lasts M consecutive times, the value of the adding counter that counts the number of times of consecutive changes in the driving frequency to the reverse direction is incremented (S2258), and the value of the adding counter for the forward direction is cleared (S2259). As a result of the increment, it is determined whether the value of the adding counters for the reverse direction exceeds the second threshold value (S2260). In a case where the value of the adding counter for the reverse direction exceeds the second threshold value (“Yes” in S2260), the adjustment amount for one step is decreased by Δx (S2261), and the value of the adding counter for the reverse direction is cleared (S2262).

The second threshold value for determining the value of the adding counter for the forward direction in S2254 and the second threshold value for determining the value of the adding counter for the reverse direction in S2260 may not identical. A second threshold value “F” may be used for determining the value of the adding counter for the forward direction, and a second threshold value “R”, which is different from the second threshold value “F”, may be used for determining the value of the adding counter for the reverse direction.

According to this processing method, the step size with which the driving frequency is adjusted is dynamically adjusted in accordance with the convergence state of the driving frequency of the MEMS mirror 15 to the resonance frequency, whereby more precise control is implemented.

### Third Embodiment

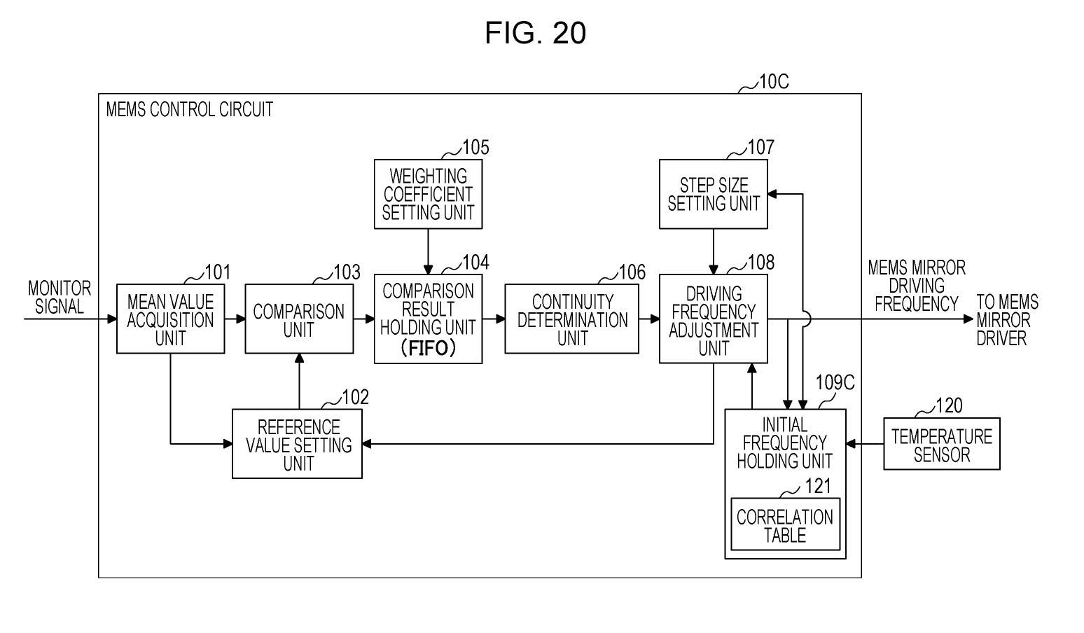

FIG. 20 is a schematic block diagram of an MEMS control circuit 10C according to the third embodiment. The identical reference numerals are given to constituent elements identical to those of the MEMS control circuit 10A according to the first embodiment, and redundant explanations are omitted.

In the third embodiment, the MEMS control circuit 10C uses temperature information from the outside. In FIG. 20, the output of a temperature sensor 120 is connected to the input of an initial frequency holding unit 109C. The initial frequency holding unit 109C holds a correlation table 121 (or correlation function) as correlation information describing the correlation between the temperature information and the driving frequency. In addition to the correlation between the temperature and the driving frequency, a correlation between the temperature and the adjustment value (step size) of the driving frequency may be described.

When the projector 1 is activated, the step size setting unit 107 refers to the correlation table 121 from the output of the temperature sensor 120 and sets, as an initial driving frequency, the driving frequency associated with the temperature. The adjustment value of the driving frequency corresponding to the temperature may be set as an initial adjustment period (initial step size).

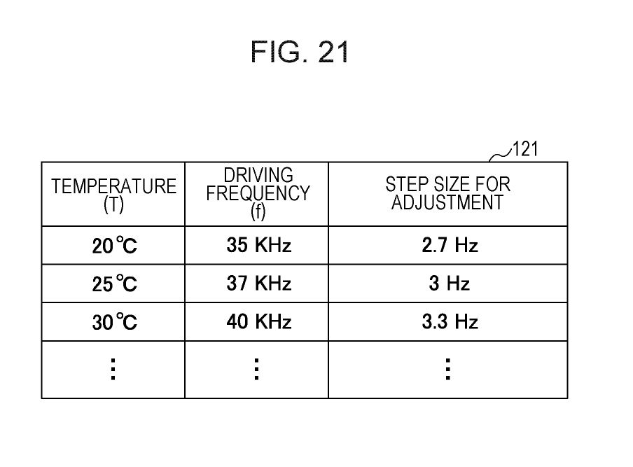

FIG. 21 illustrates an example of the correlation table 121. Corresponding to each temperature, the driving frequency (kHz) and the step size for adjustment (Hz) are described. The temperature item may be described by a temperature difference AT with respect to a certain reference temperature Tref.

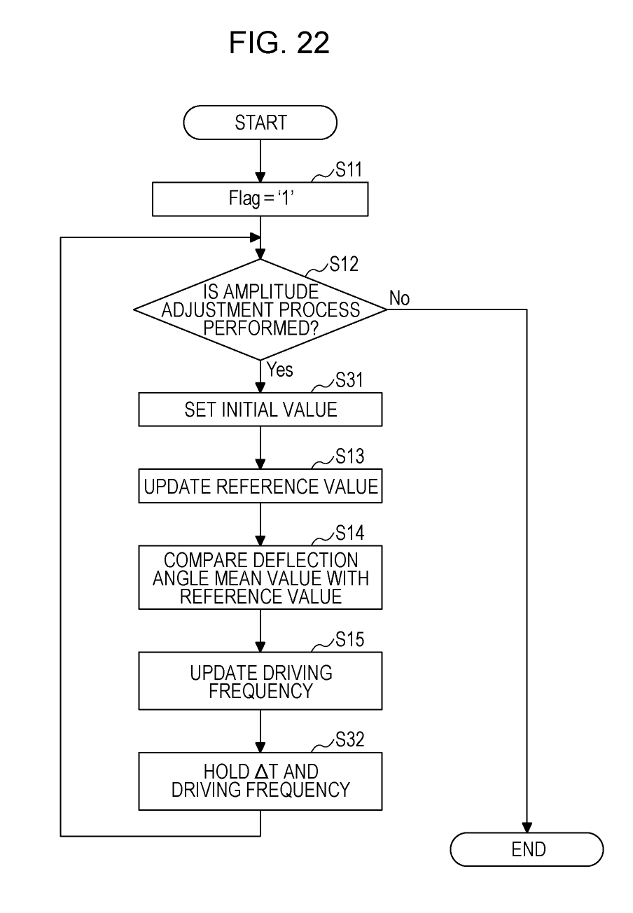

FIG. 22 is a flowchart of an operation of the MEMS control circuit 10C of the third embodiment. The identical operation numbers are assigned to processes identical to those in the first embodiment (FIG. 11), and redundant explanations are omitted.

When the projector 1 is activated, the flag is set to “1” (S11), and it is determined whether to adjust the driving frequency, that is, to perform an adjustment process of maintaining the deflection angle (amplitude) of the MEMS mirror at the maximum (S12). In a case where the flag is set to “1”, it is determined that the adjustment process is performed (“Yes” in S12), and the initial value of the driving frequency is set (S31). In the initial process immediately after power-on, the driving frequency suitable for the ambient temperature wherein the driving frequency is held in the initial frequency holding unit 109C is used based on the temperature information from the temperature sensor 120. In addition, a step size corresponding to the ambient temperature may be set as the step size at which the driving frequency is adjusted. Thereafter, the reference value is updated (S13).

The reference value that has been held last at the time of the previous activation of the projector may be used as the reference value at the initial operation. The deflection angle mean value of the monitor signal is compared with the reference value (S14), and the driving frequency is updated based on the result of the continuity determination on the comparison values (S15). The updated driving frequency and the temperature change amount AT at the time of the update are written in the correlation table 121 (S32).

Updating the correlation table 121 in operation S32 allows the correlation table 121 to be constructed and rewritten while the projector 1 is actually used. The latest driving frequency and its adjustment value may be used as initial values at the time of the next activation of the projector 1.

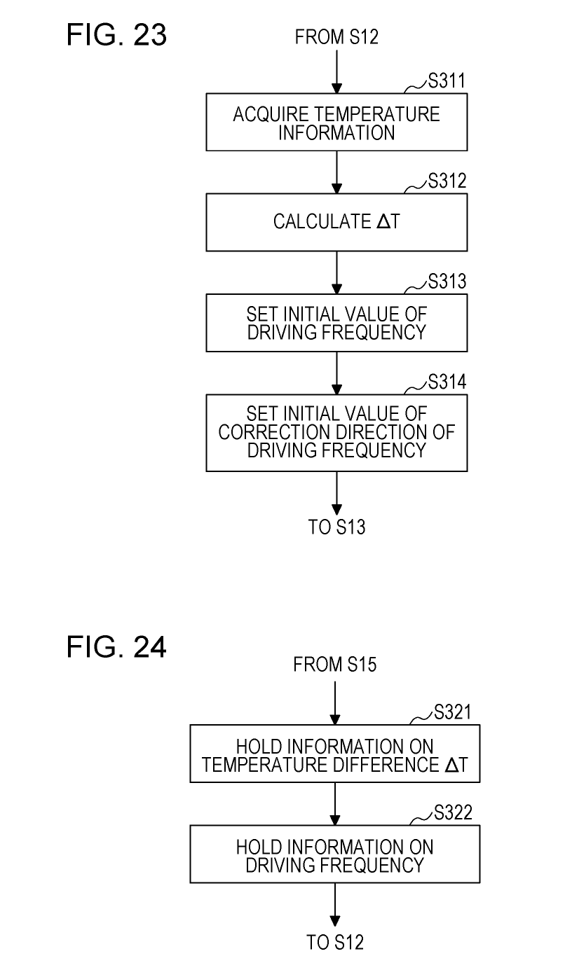

FIG. 23 is a detailed flowchart of a process of setting an initial value in operation S31 of FIG. 22. The temperature information is acquired from the temperature sensor 120 (S311). A temperature change AT from the reference temperature is calculated (S312), a driving frequency corresponding to the temperature change ΔT is selected from the correlation table 121, and set as the initial value of the driving frequency (S313). The initial values of the correction direction of the driving frequency and the step size for adjustment are set (S314). For example, since the resonance frequency increase when the temperature change ΔT is negative (lower than the reference temperature), the driving frequency is corrected to the positive direction in the initial correction direction. Since the resonance frequency decreases when the temperature change ΔT is positive, the driving frequency is corrected to the negative direction. Thereafter, the process proceeds to operation S13.

FIG. 24 is a detailed flowchart of a process of holding temperature information and driving frequency in operation S32 of FIG. 22. When the continuity determination on the comparison result is performed in operation S15 and the driving frequency is updated, the information on the temperature difference information AT and the information on the driving frequency at the time of the update are written in the correlation table 121 (S321, S322). The holding of the temperature difference information ΔT (S321) and the holding of the driving frequency information (S322) may be held simultaneously or may be held in any order.

According to this method, it is possible to set an appropriate driving frequency and an adjustment value (step size) as initial values according to the ambient temperature every time the projector 1 is activated.

Although the embodiments has been described based on specific embodiments, the embodiment is not limited to the above-described embodiments. For example, dynamic updating of the weighting coefficient and the step size of the second embodiment, and setting of the initial value according to the ambient temperature of the third embodiment may be combined. Part of the output of the weighting coefficient/step size adjustment unit 111 of the second embodiment may be used for constructing and rewriting the correlation table 121 of the third embodiment.

In any case, it is possible to cause the driving frequency to follow the resonance frequency based on the deflection angle (or amplitude) in the high speed axis direction of the MEMS mirror 15, which is directly monitored, without comparing the phases of the monitor signal and the driving signal.

At least one of the weighting coefficient of the number of times (N, M) used for continuity determination and the step size with which the driving frequency is adjusted is dynamically controlled, so that the convergence speed of the driving frequency to the resonance frequency may be increased and the range of convergence may be narrowed in the vicinity of the resonance frequency.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A micro electro mechanical systems (MEMS) control circuit comprising:
a memory; and
a processor coupled to the memory and the processor configured to:
obtain an amplitude mean value of a monitor signal representing an amplitude in a direction of a horizontal axis of an MEMS device every unit time;
compare the amplitude mean value with a reference value; and
change a driving frequency of the MEMS device in a case where identical comparison results last consecutively a predetermined number of times.

2. The MEMS control circuit according to claim 1,
wherein the processor is configured to change the driving frequency to a forward direction identical to a previous control direction with a predetermined adjustment unit in a case where results in which the amplitude mean value exceeds the reference value last N consecutive times, wherein N is a natural number more than two.

3. The MEMS control circuit according to claim 1,
wherein the processor is configured to change the driving frequency to a reverse direction reverse to a previous control direction with a predetermined adjustment unit in a case where results in which the amplitude mean value falls below the reference value last M consecutive times, wherein M is a natural number more than two.

4. The MEMS control circuit according to claim 1,
wherein the processor is configured to:
change the driving frequency to a forward direction identical to a previous control direction with a first adjustment unit in a case where results in which the amplitude mean value exceeds the reference value last N consecutive times, wherein N is a natural number more than two, and
change the driving frequency to a reverse direction reverse to the previous control direction with a second adjustment unit in a case where results in which the amplitude mean value falls below the reference value last M consecutive times, wherein M is a natural number more than two.

5. The MEMS control circuit according to claim 4,
wherein M is smaller than N.

6. The MEMS control circuit according to claim 1,
wherein the processor is further configured to set an amplitude mean value of the monitor signal over a predetermined period after the driving frequency is changed.

7. The MEMS control circuit according to claim 1,
wherein the processor is further configured to adjust a weighting coefficient of the predetermined number of times according to a magnitude of a difference between the amplitude mean value and the reference value.

8. The MEMS control circuit according to claim 7,
wherein the processor is configured to:
increase the weighting coefficient in changing the driving frequency to a forward direction identical to a previous control direction when an absolute value of the difference between the amplitude mean value and the reference value exceeds a first threshold value, and
decreases the weighting coefficient in changing the driving frequency to the forward direction when the absolute value of the difference is smaller than the first threshold value.

9. The MEMS control circuit according to claim 7,
wherein the processor is configured to:
decrease the weighting coefficient in changing the driving frequency to a reverse direction reverse to a previous control direction when an absolute value of the difference between the amplitude mean value and the reference value exceeds a first threshold value, and
increase the weighting coefficient in changing the driving frequency to the reverse direction when the absolute value of the difference is smaller than the first threshold value.

10. The MEMS control circuit according to claim 2,
wherein the processor is further configured to adjust the predetermined adjustment unit according to a count value of a number of times of consecutive changes in the driving frequency to the forward direction.

11. The MEMS control circuit according to claim 3,
wherein the processor is further configured to adjust the predetermined adjustment unit according to a count value of a number of times of consecutive changes in the driving frequency to the reverse direction.

12. The MEMS control circuit according to claim 2,
wherein the processor is further configured to increase the predetermined adjustment unit when a number of times of consecutive changes in the driving frequency to the forward direction exceeds a second threshold value.

13. The MEMS control circuit according to claim 3,
wherein the processor is further configured to decrease the predetermined adjustment unit when a number of times of consecutive changes in the driving frequency to the reverse direction exceeds a second threshold value.

14. The MEMS control circuit according to claim 1,
wherein the processor is further configured to:
store correlation information in which a temperature is associated with the driving frequency,
refer to the correlation information when acquiring temperature information, and
select a frequency associated with the temperature as an initial driving frequency.

15. The MEMS control circuit according to claim 14,
wherein the correlation information includes an adjustment unit with which the driving frequency is adjusted in association with the temperature and the driving frequency, the adjustment unit being a size with which the driving frequency is changed.

16. The MEMS control circuit according to claim 15,
wherein the correlation information is stored according to the temperature at a time when the driving frequency is changed.

17. A projector comprising:
a light source;
a micro electro mechanical systems (MEMS) mirror configured to scan light output from the light source in a predetermined direction;
a signal processing circuit configured to process a video signal; and
an MEMS control circuit configured to include a memory and a processor coupled to the memory and the processor configured to:
obtain an amplitude mean value of a monitor signal representing an amplitude in a direction of a horizontal axis of the MEMS mirror every unit time;
compare the amplitude mean value with a reference value, and
change a driving frequency of the MEMS device in a case where identical comparison results last consecutively a predetermined number of times,
wherein the MEMS control circuit controls the MEMS mirror in synchronization with a process of the video signal.
